(19) United States
(12) Patent Application Publication
(10) Pub. No.: US 2009/0195323 A1
(43) Pub. Date: Aug. 6, 2009

(54) SURFACE-MOUNT TYPE CRYSTAL OSCILLATOR

(75) Inventor: Hidenori HARIMA, Sayama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: NIHON DEMPA KOGYO CO., LTD., Tokyo (JP)

(21) Appl. No.: 12/365,756

(22) Filed: Feb. 4, 2009

(30) Foreign Application Priority Data
Feb. 5, 2008 (JP) 2008-025331

(51) Int. Cl. H03B 1/02

(52) U.S. Cl. 331/68

(57) ABSTRACT

A surface-mount type crystal oscillator includes: a container body including a base wall and a frame wall, the frame wall being arranged on one principal surface of the base wall as including an opening; a crystal blank hermetically encapsulated inside a recess of the container body, the recess being formed by the opening of the frame wall; and an IC chip in which an oscillation circuit that uses the crystal blank is integrated. A flat portion which is a part of the base wall protrudes outwardly from an outer circumference of the frame wall. The IC chip is fixed to the one principal surface of the base wall at the flat portion. A testing terminal which is electrically connected with the crystal blank is provided on the one principal surface of the base wall at the flat portion.

### BACKGROUND OF THE INVENTION

1. Field of the Invention

The present invention relates to a surface-mount type quartz crystal oscillator with less height, and in particular, relates to a surface-mount type crystal oscillator which is to be mounted on a thin electronic card (i.e., smart card) such as a SIM (subscriber identify module) card, a PC (personal computer) card, etc., or an IC (integrated circuit) card.

2. Description of the Related Art

A typical example of an electronic card which is a small card including a memory, an IC chip, etc. would be a SIM card used in a cellular phone. A SIM card in a cellular phone serves to store authentication information, etc. of a cellular phone and is used in registering permission information with respect to the cellular phone, individual information such as a phone number, and so forth. In recent years, incorporating a GPS (global positioning system) function into such a SIM card has been given consideration. In such case, because it is necessary to supply a reference frequency signal of high precision to a GPS receiving circuit, it is important that a surface-mount type temperature compensated crystal oscillator (TCXO) with less height or less thickness, designed to correspond with the thickness of the SIM card, is mounted on the SIM card. According to the SIM card standard, the thickness of the SIM card itself is specified to 0.76 mm, whereby the thickness of the surface-mount type crystal oscillator to be incorporated inside the SIM card is required to be 0.5 mm to 0.4 mm or less.

A surface-mount type crystal oscillator has a configuration in which a quartz crystal blank and an IC chip provided with an oscillation circuit that uses the crystal blank are kept inside a container for surface mounting. Such surface-mount type crystal oscillators are incorporated into various portable devices as reference sources in terms of frequency and time. A surface-mount type temperature-compensated crystal oscillator is a kind of a crystal oscillator that has a temperature compensation mechanism-embedded in the IC chip for the purpose of compensating for a temperature frequency characteristic of the crystal blank.

In general, there are some varieties of surface-mount type crystal oscillators different by sectional structures, which are, for example; a single-room type, a two-room type (also called an H-section type), a bonding type, and so forth. In the single-room type surface-mount type crystal oscillator, the crystal blank and the IC chip are accommodated and hermetically encapsulated inside a single recess that is formed in the container body.

FIG. 1A is a sectional view showing one configuration example of a conventional single-room type surface-mount type temperature-compensated crystal oscillator. FIG. 1B is a plane view of an IC chip to be used in the crystal oscillator shown in FIG. 1A.

A recess is formed at one principal surface of container body 1 which is made with laminated ceramics and formed into a flat and approximately rectangular parallelepiped shape. In an inner wall of the recess, a step is formed. On an upper surface of the step in the recess, a pair of holding terminals 9 for holding a crystal blank 3 are arranged. IC chip 2 and crystal blank 3 are kept inside the recess. In the crystal oscillator, metal ring 12 is arranged on an edge face at an opening of container body 1, i.e., on an upper surface of container body 1 that surrounds the recess. Crystal blank 3 and IC chip 2 are hermetically encapsulated in the recess by metal cover 13 and metal ring 12, metal cover 13 having been bonded to metal ring 12 by seam welding.

IC chip 2 integrates therein at least an oscillation circuit that uses crystal blank 3 and a temperature compensation mechanism which compensates for a frequency temperature characteristic of crystal blank 3, and has a planer and an approximately rectangular shape. In IC chip 2, one or more electronic circuits are formed on a one of principal surfaces of a semiconductor substrate through a normal semiconductor device fabrication process. Therefore, between the two principal surfaces of the semiconductor substrate, the one where the electronic circuits are formed is called a circuit formation surface of IC chip. On the circuit formation surface of IC chip 2, three IC terminals 4 are arranged along each long side of the circuit formation surface. IC terminals 4 are provided for connecting IC chip 2 with an external circuit, and formed as conductive pads, for instance. IC terminals 4 include a power supply terminal (Vcc), an output terminal (OUT), a ground terminal (GND), and an AFC (automatic frequency control) terminal, and also include a pair of crystal IC terminals 4x, 4y which are used in electrical connection with crystal blank 3. Among IC terminals 4, the ones serving as the power supply terminal, the output terminal, the ground terminal, and the AFC terminal are positioned at four corners of the circuit formation surface, respectively, whereas the ones serving as crystal IC terminals 4x, 4y are positioned at central regions of the two long sides of the circuit formation surface.

On an inner bottom surface of the recess of container body 1, a plurality of circuit terminals 14 are arranged in a way corresponding to IC terminals 4. IC chip 2 is fixed to the inner bottom surface of the recess using flip-chip bonding technique. More concretely, IC terminals 4 are bonded to circuit terminals 14 by ultrasonic thermocompression bonding using bumps 5.

At four corners of an outer bottom surface of container body 1, mounting terminals 6 are arranged for surface-mounting of the crystal oscillator on a wiring board. Among IC terminals 4, the ones that serve as the power supply terminal, the output terminal, the ground terminal, and the AFC terminal are electrically connected with mounting terminals 6 via the lamination plane between the ceramic layers of container body 1 by a conductive path (not shown) formed in container body 1. Crystal IC terminals 4x, 4y are electrically connected with the pair of holding terminals 9 by a conductive path (not shown) formed in container body 1.

As shown in FIG. 2B described later, crystal blank 3 is an AT-cut quartz crystal blank of an approximately rectangular shape, for instance, and excitation electrodes 7a, 7b are formed on both principal surfaces of crystal blank 3, respectively. Extraction electrodes 8a, 8b are extending from respective excitation electrodes 7a, 7b toward both corners of one end of crystal blank 3. Each of extraction electrodes 8a, 8b is formed as being folded back to the other principal surface of crystal blank 3 at the end of crystal blank 3. Extraction electrodes 8a, 8b are secured to holding terminals 9 by conductive adhesive 10 at the positions to which extraction electrodes 8a, 8b are extended, thereby crystal blank 3 being kept inside the recess of container body 1 and electrically connected with IC chip. Since conductive adhesive 10 is applied only on holding terminals 9 in the process of fixing crystal blank 3, there is no conductive adhesive being applied on the upper surface, which is shown in the figure, of crystal blank 3.

On the outer side surfaces of container body 1, a pair of testing terminals 11 are arranged. Holding terminals 9 are also electrically connected with the testing terminals 11. Testing terminals 11 are used in measuring a vibration characteristic of crystal blank 3 as a stand-alone piece. Such testing terminals 11 are formed on end surfaces of respective ceramic layers configuring container body 1. However, in container body 1, which is configured by stacking a plurality of ceramic layers, testing terminals 11 are not formed on end surfaces of a top layer and a bottom layer, considering possible electrical short-circuit with metal ring 12, the wiring board, or the like.

Therefore, the length of testing terminal 11 is less than the height of container body 1 in a height direction of the crystal oscillator.

In the description above, mounting terminals 6, holding terminals 9, testing terminals 11 and circuit terminals 14 are formed as electrode layers on the surfaces of the laminated ceramics.

Among the varieties of surface-mount type crystal oscillators, the two-room type is a kind in which the crystal blank is hermetically encapsulated in a first recess formed on one of principal surfaces of the container body while the IC chip is contained in a second recess formed on the other principal surface of the container body. In this way, a sectional shape of the container body will become an H character shape. In the container body, the mounting terminals are arranged at four corners of a surface which surrounds the second recess. In this case, crystal testing terminals are arranged on outer side surfaces of the container body or on a bottom surface of the second recess.

Among the varieties of surface-mount type crystal oscillators, the bonding type is configured in a way such that the mounting substrate, which contains the IC chip and is provided with mounting terminals, is bonded to a quartz crystal unit which is configured as hermetically encapsulating the crystal blank inside the container. IC chip 2 is electrically connected with the crystal blank and the mounting terminals in the same way as described above. In this case, the terminals used in bonding the crystal unit to the mounting substrate can also be used as the crystal testing terminals. As one example of the bonding type crystal oscillator, Japanese Patent Laid-Open No. 2002-330027 (JP-2002-330027A) discloses a kind in that an assembly configured by bonding the IC chip to a lead frame is bonded to the crystal unit.

In any of the varieties of the surface-mount type crystal oscillators, i.e., the single-room type, the two-room type, and the bonding type, when the crystal oscillator is configured as a temperature-compensated crystal oscillator, temperature compensation data is written into the temperature compensation mechanism inside the IC chip using mounting terminals 6, which are arranged as corresponding to the power supply terminal, the AFC terminal, etc., as writing terminals. By writing the temperature compensation data corresponding to the frequency temperature characteristic of the crystal blank into the temperature compensation mechanism, it will be possible to compensate for frequency fluctuation that originates from the crystal blank depending on temperature. It is also possible to arrange the writing terminals at the outer surfaces of the container body, separately from the mounting terminals.

However, in any of the varieties of the surface-mount type crystal oscillators with the configurations described above, the IC chip and crystal blank 3 are arranged in the height direction of the crystal oscillator. Therefore, the lower limit of height of the crystal oscillator will be about 0.8 mm. The above-described surface-mount type crystal oscillators are not suitable for use in the SIM card which requires a crystal oscillator with a height of about 0.5 mm or less.

Japanese Patent Laid-Open Application No. H09-83248 (JP-9-083248A) discloses a way of reducing the height of the crystal oscillator by arranging an IC chip and a crystal blank side by side in a lateral direction on an inner bottom surface of a recess. FIGS. 2A and 2B are a sectional view and a plane view, respectively, of the crystal oscillator in which IC chip 2 and crystal blank 3 are arranged in the lateral direction on the bottom surface of the recess in container body 1. In this case, the step is not formed in the inner side surface of the recess, and the pair of holding terminals 9 are arranged directly on the inner bottom surface of the recess.

Considering a thickness of the IC chip including the bumps, a distance between the IC chip and the metal cover, and a thickness of the metal cover, by arranging the IC chip and crystal blank 3 side by side in the lateral direction on the inner bottom surface of the recess in the container body as described above, the height of the crystal oscillator can be reduced to about 0.5 mm. Instead of using the flip-chip bonding method using bumps it is also possible to use a method of electrically connecting the IC chip and the container body using wire bonding. In the latter case also, the height of the crystal oscillator can be reduced to about 0.5 mm. However, with the conventional crystal oscillator adopting the method of using bumps or using wire bonding, it is difficult to further reduce the height of the crystal oscillator to less than 0.5 mm.

Moreover, in the case of reducing the height of the crystal oscillator in the above-described way, the height of the container body will also be reduced, whereby the testing terminals formed on the outer side surfaces of the container body will become smaller, and in particular, the lengths of the testing terminals will become shorter in the height direction of the container body. Due to the testing terminals becoming smaller, it will be difficult for a probe of a measuring device to contact with the testing terminals.

In a crystal oscillator disclosed in U.S. Patent Publication No. 2004/0113708 (US-2004/0113708A), a frame body with an opening formed at a central portion thereof is mounted on a plate-like substrate, and an IC chip and a crystal blank are arranged in a space surrounded by the frame body. The substrate is larger in size than an outer circumference of the frame body, and circuit elements such as a capacitor, etc. are arranged in a region of the substrate which is not surrounded by the frame body.

Japanese Patent Laid-Open Application No. H10-22735 (JP-10-022735A) discloses a crystal oscillator with a configuration in which a container body of a laminated structure including a plate-like base wall and a frame wall with a central opening is used, and a crystal blank and an IC chip are hermetically accommodated inside a recess formed by the frame wall. In this crystal oscillator, the base wall is larger in size than an outer circumference of the frame wall, and writing terminals for writing temperature compensation data are formed on the base wall at positions outside a formation region of the frame wall.

### SUMMARY OF THE INVENTION

It is therefore an object of the present invention to provide a surface-mount type crystal oscillator of which height can be reduced by arranging an IC chip and a crystal blank in a lateral direction on an inner bottom surface of a recess in a container body, and which is capable of facilitating contacting of a probe with crystal testing terminals.

A surface-mount type crystal oscillator according to the present invention includes: a container body including a base wall and a frame wall, the frame wall being arranged on one principal surface of the base wall as including an opening; a crystal blank hermetically encapsulated inside a recess of the container body, the recess being formed by the opening of the frame wall; an IC chip in which at least an oscillation circuit that uses the crystal blank is integrated, wherein a flat portion which is a part of the base wall protrudes outwardly from an outer circumference of the frame wall, the IC chip being fixed to the one principal surface of the base wall at the flat portion, and wherein a testing terminal which is electrically connected with the crystal blank is provided on the one principal surface of the base wall at the flat portion.

With this configuration, since it is only the crystal blank that is to be contained inside the recess of the container body, it is possible to determine a height of the container body only considering a thickness of the crystal blank and without considering a height of the IC chip including the bumps, whereby the height of the container body can be reduced. In this case, the height of the IC chip fixed to the flat portion can be made less than a height of the frame wall even when thicknesses of the bumps and the resin mold are taken into consideration. Therefore, a height of the crystal oscillator as a whole can be reduced.

Moreover, since the testing terminals are arranged on the surface of the flat portion, it is possible to form the testing terminals into desired sizes regardless of the height of the container body. With this configuration, it will be possible to facilitate contacting of the probe with the testing terminals, whereby a vibration characteristic of the crystal blank will be able to be measured reliably.

### BRIEF DESCRIPTION OF THE DRAWINGS

FIG. 1A is a sectional view showing an example of a configuration of a conventional surface-mount type temperature-compensated crystal oscillator;

FIG. 1B is a plane view of an IC chip;

FIG. 2A is a sectional view showing another example of a configuration of a conventional surface-mount type temperature-compensated crystal oscillator;

FIG. 2B is a plane view of the crystal oscillator shown in FIG. 2A, the crystal oscillator being in a state without a cover;

FIG. 3A is a sectional view showing a configuration of a surface mount type temperature-compensated crystal oscillator according to one exemplary embodiment of the present invention;

FIG. 3B is a plane view of the crystal oscillator shown in FIG. 3A, the crystal oscillator being in a state without a cover and a resin mold;

FIG. 4A is a sectional view showing a configuration of a surface-mount type temperature-compensated crystal oscillator according to another exemplary embodiment of the present invention;

FIG. 4B is a plane view of the crystal oscillator shown in FIG. 4A, the crystal oscillator being in a state without a cover and a resin mold; and

FIGS. 5A and 5B are plane views of surface-mount type temperature compensated crystal oscillators according to other different exemplary embodiments of the present invention, each of the surface-mount type temperature-compensated crystal oscillators being in a state without a cover and a resin mold.

### DETAILED DESCRIPTION OF THE PREFERRED EMBODIMENTS

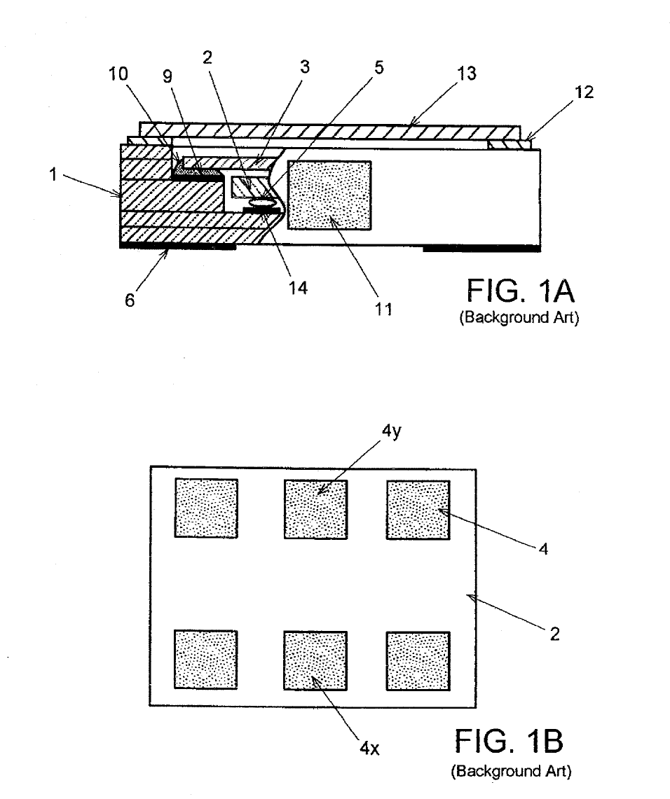

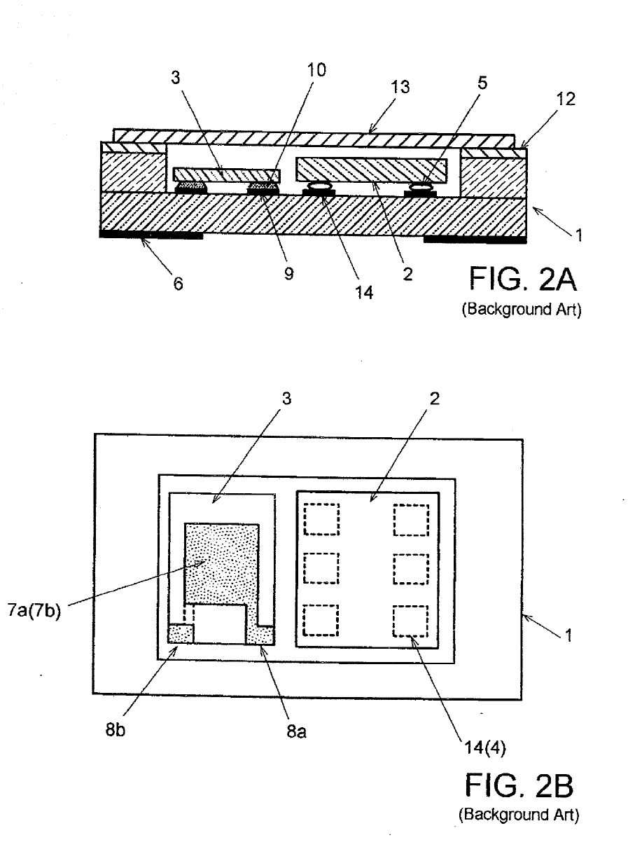

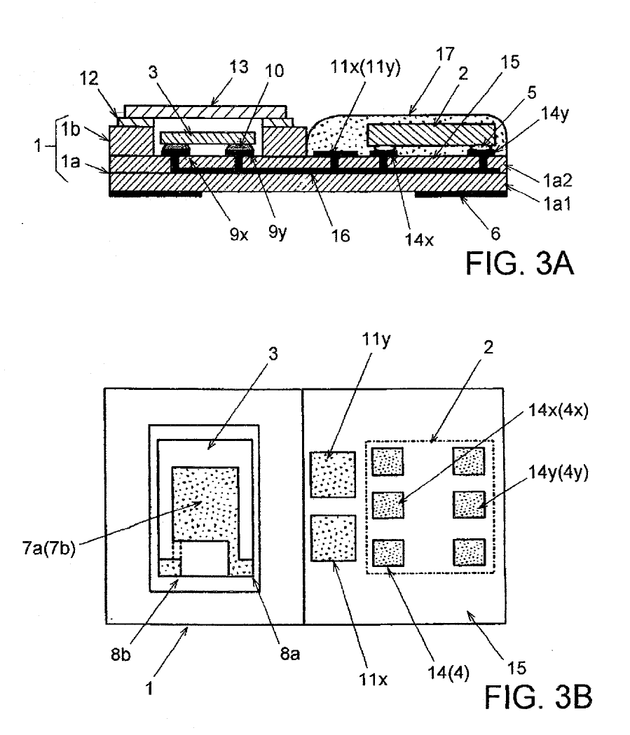

With respect to FIGS. 3A and 3B showing a surface-mount type temperature-compensated crystal oscillator according to one exemplary embodiment of the present invention, the same reference numerals as used in FIGS. 1A, 1B, 2A and 2B will be used for referring to the same constituent elements as those in FIGS. 1A, 1B, 2A and 2B, and redundant descriptions with respect to them will be omitted.

As with the crystal oscillator shown in FIGS. 2A and 2B, the crystal oscillator of the present embodiment is configured in a way such that IC chip 2 and crystal blank 3 are mounted on container body 1 made with laminated ceramics. Container body 1 is formed in a laminated structure including a plate-like base wall 1a of an approximately rectangular shape, and frame wall 1b formed on base wall 1a. An opening of an approximately rectangular shape is formed in the center of frame wall 1b. A side wall of a recess in container body 1 is formed by an inner circumference surface of frame wall 1b. A part of base wall 1a which is exposed by the opening of frame wall 1b forms an inner bottom surface of the recess. As shown in the drawing, base wall 1a is formed in a laminated structure including lower layer 1a1 shown in a lower side and upper layer 1a2 shown in an upper side. An outer circumference dimension of base wall 1a is larger than an outer circumference dimension of frame wall b. Therefore, frame wall 1b, for example, is arranged only in a left half region of base wall 1a shown in the drawings. Frame wall 1b is not formed in the right half region of base wall 1a, and the right half region is flat portion 15 where an upper surface of base wail 1a is exposed. In other words, base wall 1a is protruding from the outer circumference of frame wall 1b to the right, and this protruding part of base wall 1a is flat portion 15 of base wall 1a.

A pair of holding terminals 9x, 9y are arranged on the inner bottom surface of the recess in container body 1. Crystal testing terminals 11x, 11y, and circuit terminals 14 are Formed on a surface of flat portion 15. Here, the surface of flat portion 15 and the inner bottom surface of the recess belong to the same principal surface of base wall 1a. Circuit terminals 14 are arranged in a way corresponding to IC terminals 4 of IC chip 2. In this case, crystal testing terminals 11x, 11y are formed in an area between a formation region of frame wall 1b and a formation region circuit terminals 14. As in the above-described case, mounting terminals 6 are arranged at four corners of the other principal surface of base wall 1a, i.e., at four corners of an outer bottom surface of container body 1.

The pair of holding terminals 9x, 9y are electrically connected with a pair of crystal circuit terminals 14x, 14y among circuit terminals 14. Crystal circuit terminals 14x, 14y corresponds to crystal IC terminals 4x, 4y among IC terminals 4, respectively. The pair of holding terminals 9x, 9y are also electrically connected with crystal testing terminals 11x, 11y, respectively. Such electrical connections are made possible by electrode thorough-holes such as through-holes, via-holes, etc., which are arranged in base wall 1a, and by conductive path 16 formed on a lamination plane between lower layer 1a1 and upper layer 1a2 of the base wall. Among circuit terminals 14, the ones that serve as a power supply terminal, an output terminal, a ground terminal, and an AFC terminal are electrically connected with mounting terminals 6 by conductive path, which is not shown.

Crystal blank 3 in this case can be the one shown in FIG. 2B and used as it is. At both corners of one end of crystal blank 3 to which extraction electrodes 8a, 8b are extended from excitation electrodes 7a, 7b, crystal blank 3 is secured to holding terminals 9x, 9y by conductive adhesive 10. Thereby, crystal blank 3 is kept inside the recess of container body 1 and hermetically encapsulated in the recess by metal cover 13 and a metal ring. The metal ring is arranged on an upper surface of frame wall 1b in a way surrounding the opening of the recess, and metal cover 13 and the metal ring are bonded by seam welding. In the present embodiment, a crystal unit in which only crystal blank 3 is hermetically encapsulated inside the recess is configured, which is different from the configurations of the crystal oscillators shown in FIGS. 1A, 1B, 2A and 2B.

In a process of manufacturing such a crystal oscillator, by securing crystal blank 3 to holding terminals 9x, 9y by a conductive adhesive, testing terminals 11x, 11y will be electrically connected to excitation electrodes 7a, 7b of crystal blank 3 via extraction electrodes 8a, 8b. In this state, by letting a probe of a measuring device contact testing terminals 11x, 11y, it will be possible to measure a vibration characteristic of crystal blank 3. Prior to bonding metal cover 13 to the metal ring, vibration frequency of crystal blank 3 can be adjusted by reducing the mass of excitation electrode 7a on the exposed side with a sputtering effect which can be brought about by irradiating excitation electrode 7a with an ion beam using an ion gun, such process to be taking place while the vibration frequency of crystal blank 3 is measured using testing terminals 11x, 11y.

After the test of the vibration characteristic of crystal blank 3 using testing terminals 11x, 11y, IC chip 2 which at least integrates therein an oscillation circuit and a temperature compensation mechanism is to fixed to flat portion 15 by flip-chip bonding. More specifically, IC terminals on a circuit formation surface of IC chip 2 are bonded to circuit terminals 14 on flat portion 15 by ultrasonic thermal compression bonding using bumps 5. After that, whole IC chip 2 along with testing terminals 11x, 11y are sealed with resin mold 17. IC chip 2 in this case can be the one shown in FIG. 1B or FIG. 2B.

In the crystal oscillator according to the present embodiment, the crystal unit is formed by letting only crystal blank 3 be contained inside the recess of container body 1, and IC chip 2 is fixed to flat portion 15 which is formed by a part of base wall 1a protruding from frame wall 1b. Accordingly, it is possible to determine a height of container body 1 only considering a necessary thickness of the crystal unit that includes crystal blank 3, without considering a thickness of IC chip 2 in its state including bumps 5, whereby the height of container body 1 can be reduced. In this case, because IC chip 2 is secured to the surface of flat portion 15, in considering a height of the crystal oscillator, it is not necessary to give consideration to a distance between IC chip 2 and metal cover 13, and a thickness of metal cover 13. Even when a thickness of resin mold 17 is counted, a height of IC chip 2 as including base wall 1a and bumps 5 can be made less than a height of the crystal unit portion where crystal blank 3 is hermetically encapsulated.

Assuming that crystal blank 3 is an AT-cut quartz crystal blank and vibration frequency thereof is 26 MHz, the thickness of crystal blank 3 will be 64 μm. From a mechanical strength perspective, base wall 1a of the container body can be rendered as thick as 130 μm, for example. Considering a distance between crystal blank 3 and the inner bottom surface of the recess, and a distance between crystal blank 3 and metal cover 13, a combined thickness of metal ring 12 and frame wall 1b can be rendered 200 μm, for example. In the crystal oscillator according to the present embodiment, since metal cover 13 can be formed to a thickness of 70 μm, the height of the crystal unit portion can be rendered 400 μm, i.e., 0.4 mm. Furthermore, IC chip 2 of a thin type can be 120 μm thick, for instance, and bump 5 can be 40 μm thick, for instance. Resin mold 17 with respect to a thick part thereof arranged directly on flat portion 15 can be rendered as thick as 220 μm, for example. In this case, a part of resin mold 17 on IC chip 2 will be 60 μm thick, for example. Accordingly, even when the thickness of base wall 1a is included, the height of the crystal oscillator at an arrangement region of IC chip 2 will be 350 μm.

In this way, the surface-mount type temperature-compensated crystal oscillator according to the present embodiment will be as high as 0-4 mm depending on the height of the crystal unit portion. Such a crystal oscillator will meet the requirement that the thickness of the crystal oscillator is to be 0.5 mm or less in its use in a SIM card, for instance.

In the crystal oscillator of the present embodiment, since testing terminals 11x, 11y are formed on flat portion 15 which is a periphery portion of base wall 1a, testing terminals 11x, 11y can be formed into necessary sizes regardless of the height of container body 1. With this type of a temperature-compensated crystal oscillator, as according to the established standard, an overall dimension will be 3.2×2.5 mm, for instance. Therefore, the size of testing terminals 11x, 11y will be about 0.4×0.4 mm. With the size to such extent, the probe can easily contact with testing terminals 11x, 11y, whereby the vibration characteristic of the crystal blank will be able to be measured without fail.

In the crystal oscillator of the above-described embodiment, crystal testing terminals 11x, 11y are arranged in between the recess and the arrangement position of IC chip 2. This configuration, when considering a clearance in arranging IC chip 2 and crystal testing terminals 11x, 11y, is advantageous in terms of area reduction since IC chip 2 and crystal testing terminals 11x, 11y are to share the same clearance.

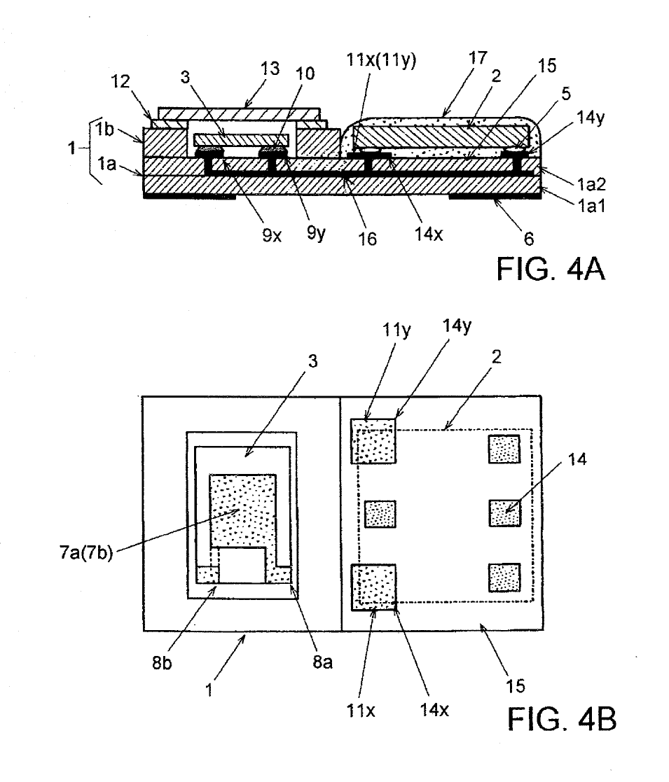

In the crystal oscillator of the above-described embodiment, crystal circuit terminals 14x, 14y, and testing terminals 11x, 11y are formed separately at flat portion 15. However, as shown in FIGS. 4A and 4B, for instance, crystal circuit terminals 14x, 14y can be arranged such that crystal circuit terminals 14x, 14y can also be used as testing terminals 11x, 11y. In the case of the crystal oscillator shown in FIGS. 4A and 4B, the IC terminals at both corners of one long side of IC chip 2 are crystal IC terminals 4x, 4y while crystal circuit terminals 14x, 14y arranged as corresponding to crystal IC terminals 4x, 4y are arranged such that areas of crystal circuit terminals 14x, 14y will be larger than the other circuit terminals. With such large-area crystal circuit terminals 14x, 14y, it is possible to let the probe contact with crystal circuit terminals 14x, 14y. Such large area crystal circuit terminals 14x, 14y can be used as crystal testing terminals 11x, 11y at the same time. In this case, it is advantageous in a perspective that a length of base wall 1a can be made shorter, or a size of IC chip 2 mounted on flat portion 15 of base wall 1a can be made larger.

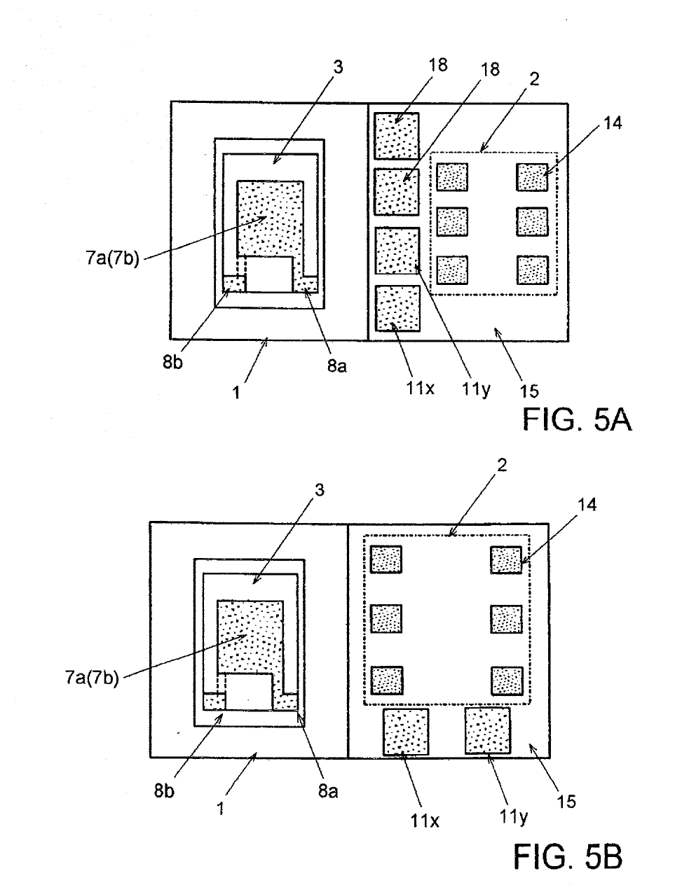

Furthermore, as shown in FIG. 5A, not only testing terminals 11x, 11y, but also writing terminals 18 for writing temperature compensation data can be arranged at flat portion 15. In the case of arranging writing terminals 18 on the surface of flat portion 15, it is possible to make areas of the writing terminals larger as compared to the case of having the writing terminals arranged on outer side surfaces of the container body, or elsewhere. Therefore, writing of temperature compensation data can be performed reliably. In a case where the mounting terminals such as the power supply terminal are capable of being used in writing temperature compensation data, it is not necessary to arrange independent writing terminals.

The positions of testing terminals 11x, 11y are not limited to the ones in between the recess and IC chip 2. For instance, as shown in FIG. 5B, it is also possible to have testing terminals 11x, 11y arranged on flat portion 15 along the outer circumference of flat portion 15. Moreover, flat portion 15 can also be formed by letting only lower layer 1a1 of base wall 1a protrude from the outer circumference of frame wall 1b.

In the above-described embodiments, although metal cover 13 is bonded to frame wall 1b by seam welding, it is also possible to use a method other than the seam welding in bonding metal cover 13. For example, electronic beam welding, a bonding method using eutectic alloy, or the like can be used.

Although the above-described embodiments are about surface-mount type crystal oscillators which are a temperature compensation type, the present invention can also be applied to a surface-mount type simple packaged crystal oscillator (SPXO) which does not require temperature compensation. It is to be understood that various changes and modifications of the present invention can be made by one skilled in the art without departing from the spirit or the scope of the invention.

What is claimed is:

1. A surface-mount type crystal oscillator comprising:
a container body including a base wall and a frame wall, the frame wall being arranged on one principal surface of the base wall as including an opening;
a crystal blank hermetically encapsulated inside a recess of the container body, the recess being formed by the opening of the frame wall; and
an IC chip in which at least an oscillation circuit that uses the crystal blank is integrated,
wherein a flat portion which is a part of the base wall protrudes outwardly from an outer circumference of the frame wall, the IC chip being fixed to the one principal surface of the base wall at the flat portion, and
wherein a testing terminal which is electrically connected with the crystal blank is provided on the one principal surface of the base wall at the flat portion.

2. The crystal oscillator according to claim 1, wherein at least the testing terminal and the IC chip are covered with a resin mold at the flat portion.

3. The crystal oscillator according to claim 1, wherein the testing terminal is arranged in an area of the flat portion that is between an arrangement region of the frame wall and an arrangement region of the IC chip.

4. The crystal oscillator according to claim 1, wherein the IC chip includes a temperature compensation mechanism which serves to compensate for a frequency temperature characteristic of the crystal blank.

5. The crystal oscillator according to claim 4, further comprising:
a writing terminal which is used for writing temperature compensation data into the temperature compensation mechanism, the writing terminal being provided on the one principal surface of the base wall at the flat portion.

6. The crystal oscillator according to claim 1, further comprising:
a plurality of circuit terminals provided on the one principal surface of the base wall at the flat portion, wherein
the IC chip is fixed to the circuit terminals by ultrasonic thermocompression bonding using a bump.

7. The crystal oscillator according to claim 6, wherein
from among the plurality of circuit terminals, a crystal circuit terminal that is electrically connected with the crystal blank is formed as the testing terminal and as being larger in area than the other circuit terminals.
